(19) United States
(12) Patent Application Publication
(10) Pub. No.: US 2020/0127685 A1
(43) Pub. Date: Apr. 23, 2020

(54) SYSTEMS AND METHODS FOR A HYBRID NON-VOLATILE STORAGE SYSTEM

(71) Applicant: Nyquist Semiconductor Limited, Grand Cayman (KY)

(72) Inventors: Jie Chen, Milpitas, CA (US); Xiaoming Zhu, San Jose, CA (US); Bo Fu, Cupertino, CA (US); Zining Wu, Los Altos, CA (US)

(21) Appl. No.: 16/166,003

(22) Filed: Oct. 19, 2018

(51) Int. Cl. H03M 13/29; H03M 13/15; H03M 13/11; G06F 11/10; G11C 29/52

(52) U.S. Cl. CPC H03M 13/2906; H03M 13/152; G11C 29/52; G06F 11/1068; H03M 13/1102

(57) ABSTRACT

Systems, apparatus and methods are provided for providing a flexible error correction code (ECC) architecture in a non-volatile storage system. A method for storing data may comprise generating a first error correction code (ECC) engine tag for a piece of data to be stored in a non-volatile storage device, routing the piece of data to a first type of ECC encoder of a plurality of types of ECC encoders according to the first ECC engine tag, encoding the piece of data using the first type of ECC encoder to generate ECC codeword(s) and transmitting the ECC codeword(s) to the non-volatile storage device for storage.

### TECHNICAL FIELD

The disclosure herein relates to non-volatile storage, particularly relates to a non-volatile storage system with a flexible error correction code (ECC) architecture.

### BACKGROUND

Computing systems have traditionally used a wide variety of non-volatile storage devices to maintain and store data and instructions, for example, floppy disks, hard drives, magnetic tapes, optical discs. More recently, non-volatile NAND storage devices have gained wide usage in memory cards, USB flash drives and solid-state drives (SSDs). With huge demand in various applications, different kinds of non-volatile memories have been developed. Each non-volatile memory, however, has different characteristics such as operation sequence, interface throughput, access latency, P/E cycles, endurance, retention, as well as raw bit error rate (which requires different ECC capability). Therefore, there is a need in the art for a more robust ECC architecture that can handle and take advantage of different kinds of non-volatile memories (NVMs) or different NVMs that have different qualities.

### SUMMARY

The disclosed subject matter relates to systems, methods, and devices that support various non-volatile storage devices, which also may be referred to as non-volatile memories (NVMs), such as NAND flash memories (including but not limited to, Single-Level Cell (SLC)/Multi-Level Cell (MLC)/Quad-Level Cell (QLC), etc), and 3D Xpoint (3DXP) memories). Each different kind of non-volatile memories may exhibit different characteristics such as operation sequence, interface throughput, access latency, PROGRAM/ERASE (P/E) cycles, endurance, retention, as well as raw bit error rate (which may require different ECC capability), programming time. Moreover, even the same kind of non-volatile memories, the characteristics may vary because of different factors such as increased PIE cycles, and interference between different pages/cells, etc. In general, an ECC engine may be designed to protect user data (stored in the media) from corruption by adding redundant info (i.e., parity), or increase the error tolerance of the user data. Different characteristics may demand different ECC capabilities. For example, a multi-bit cell (e.g., TLC/QLC) NAND flash may need a high performance and intelligent ECC engine to achieve a low data failure rate. In addition, when the NAND device is “new”, the raw bit error rate may be low and an ECC engine may operate at low power mode; when the NAND device is getting “old”, an ECC engine may need to operate at high performance mode.

An exemplary robust ECC system may consider correction capability, ECC latency, and power consumption. When a system is equipped with either high performance (low access latency, low raw BER, etc) non-volatile memories or high capacity (high access latency, high raw BER, etc) non-volatile memories, or both kinds of non-volatile memories, conventional ECC system cannot meet the challenge but embodiments according to the present disclosure may provide a unified flexible ECC system to accommodate all different configurations. For example, embodiments may provide a flexible or adaptive ECC system to address high performance non-volatile storage devices (e.g., NVMs (non-volatile memories)), high capacity NVMs, low performance/quality NVMs, any future emerging NVM and/or, combinations of any of the above. Moreover, embodiments may provide easy optimization for low latency, high ECC correction capability, or both.

In some embodiments, a plurality of types of ECC encoders and decoders may be implemented in an ECC processor. For example, a first type of encoder and decoder may be configured for ultra-low latency and high throughput, a second type of encoder and decoder may be configured for balanced latency and throughput, and a third pair of encoder and decoder may be configured for ultra-high correction capability and ultra-high throughput. In addition, other types of encoders and decoder included for other purposes. The combination or concatenation of any type of ECC encoder or decoder may be treated as one of the plurality of types of ECC encoder or decoder. In at least some embodiments, a memory cross-bar may be used to route the ECC codeword. For example, during a read operation, the memory cross-bar may be used to route the ECC codeword retrieved from a NVM to a corresponding ECC decoder by utilizing the ECC engine tag.

An exemplary non-volatile storage system including a flexible or adaptive ECC system may be a multi-channel SSD system that supports various non-volatile memories and/or combinations of non-volatile memories while considering latency and correction capability. One embodiment may be a high-performance NVM system with a first type of encoder and decoder to achieve the best performance in terms of latency and high throughput, and a second type of encoder and decode to provide ultra-high performance in terms of correction capability when needed.

Another embodiment may be a mixed-quality NAND system with a first type of encoder and decoder to achieve balanced performance and correction ability for high-quality NAND, and a second type of encoder and decoder used to achieve ultra-high performance in terms of correction capability and throughput. Moreover, all NANDs may be switched to the second type of encoder and decoder when needed. The switching may be determined based on the NAND characteristics, such as error count, PROGRAM/ERASE (P/E) cycle, programming time, access latency, etc.

Yet another embodiment may be a Hybrid SSD system with a first type of encoder and decoder configured for high-performance NVM (such as MRAM, 3DXP and etc.), a second type of encoder and decoder configured for regular NVM (such as high-quality NAND), and a third type of encoder and decoder configured used for low-quality NVM. In at least some embodiments with multiple types of ECC encoders and decoders, the ECC encoders or decoders are not tied with any specific physical channel and can be assigned on-the-fly during operation.

In an exemplary embodiment, there is provided a method for storing data. The method may comprise generating a first error correction code (ECC) engine tag for a piece of data to be stored in a non-volatile storage device, routing the piece of data to a first type of ECC encoder of a plurality of types of ECC encoders according to the first ECC engine tag, encoding the piece of data using the first type of ECC encoder to generate ECC codeword(s) and transmitting the ECC codeword(s) to the non-volatile storage device for storage.

In another exemplary embodiment, there is provided a storage system that may comprise a storage controller and a microcontroller. The storage controller may comprise an error correction code (ECC) processor that includes a plurality of types of ECC encoders and a plurality of types of ECC decoders. Each type of ECC encoder of the plurality of types of ECC encoders may be configured to perform encoding according to a distinctive set of encoding characteristics, and each type of ECC decoder of the plurality of types of ECC decoders may be configured to perform decoding according to a distinctive set of decoding characteristics. The microcontroller may be configured to generate an ECC engine tag indicating which of the plurality of types of ECC encoders or the plurality of types of ECC decoders to use during operation.

In yet another exemplary embodiment, there is provided a non-transitory machine-readable medium having information, wherein the information, when read by a hardware processor system, causes the hardware processor system to perform: receiving a piece of data to be stored in a non-volatile storage system, determining a set of encoding characteristics to be applied in an encoding operation, generating an error correction code (ECC) engine tag to be associated with the piece of data, and routing the piece of data to an ECC encoder selected from a plurality of types of ECC encoders according to the ECC engine tag for the piece of data to be encoded into one or more ECC codewords and stored in a non-volatile storage device of the non-volatile storage system.

### BRIEF DESCRIPTION OF FIGURES

FIG. 1 schematically shows a non-volatile storage controller in accordance with an embodiment of the present disclosure.

FIG. 2 schematically shows a non-volatile storage controller in accordance with an embodiment of the present disclosure.

FIG. 3 schematically shows a non-volatile storage system in accordance with an embodiment of the present disclosure.

FIG. 4 schematically shows a non-volatile storage system in accordance with another embodiment of the present disclosure.

FIG. 5 schematically shows a non-volatile storage system in accordance with yet another embodiment of the present disclosure.

FIG. 6 is a flowchart of a process for programming a non-volatile storage device in accordance with an embodiment of the present disclosure.

FIG. 7 is a flowchart of another process for programming a non-volatile storage device in accordance with an embodiment of the present disclosure.

FIG. 8 is a flowchart of a process for reading from a non-volatile storage device in accordance with an embodiment of the present disclosure.

### DETAILED DESCRIPTION

Specific embodiments according to the present disclosure will now be described in detail with reference to the accompanying figures. Like elements in the various figures are denoted by like reference numerals for consistency.

The present disclosure provides apparatuses, systems and methods that support various high-speed non-volatile memories (NVMs) and any combination of various NVMs. As used herein, a non-volatile memory device may be a computer storage device that can maintain stored information after being powered off, and the stored information may be retrieved after being power cycled (turned off and back on). Non-volatile storage devices may include floppy disks, hard drives, magnetic tapes, optical discs, NAND flash memories, NOR flash memories, Magnetoresistive Random Access Memory (MRAM), Resistive Random Access Memory (RRAM), Phase Change Random Access Memory (PCRAM), Nano-RAM, etc. In the description, a NAND flash may be used an example for the proposed techniques. However, various embodiments according to the present disclosure may implement the techniques with other kinds of non-volatile storage devices.

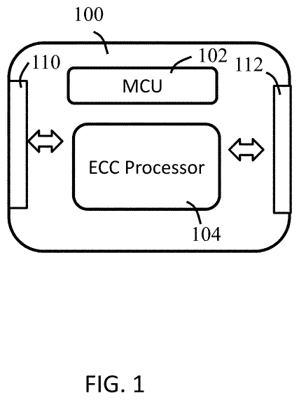

FIG. 1 schematically shows an exemplary non-volatile storage controller 100 according to an embodiment. The non-volatile storage controller 100 may comprise a first interface 110, a second interface 112, a microcontroller unit (MCU) 102 and an ECC processor 104. The first interface 110 may be any existing or yet to be developed interface that is configured to couple the non-volatile storage controller 100 to a system bus of a host computing system, and receive data from and transmit data to the host computing system. In one embodiment, for example, the first interface 110 may be an Advanced eXtensible Interface (AXI). The second interface 112 may be any existing or yet to be developed interface that is configured to couple a storage controller to one or more non-volatile storage devices. In one embodiment, the second interface 112 may be a multi-channel interface that may be configured to transfer encoded data (e.g., ECC codewords) over multiple channels in parallel. For example, the second interface 112 may be an Open NAND Flash Interface (ONFI) that may support different protocols (e.g., Non-volatile Double Data Rate (NVDDR), NVDDR Type 2 (NVDDR2,) NVDDR Type Three (NVDDR3), and Toggle protocols) and run at different transfer speeds.

The MCU 102 may be a computer processor configured to execute executable instructions (e.g., software or firmware). In various embodiments, the MCU 102 may be a microprocessor, a microcontroller, a field-programmable gate array (FPGA), or an application-specific IC (ASIC). The ECC processor 104 may comprise a plurality of types of ECC encoders and a plurality of types of ECC decoders. During a program operation (e.g., a write operation), the MCU 102 may generate an ECC engine tag for a piece of data received from a host to indicate which type of ECC encoder may be used to encode the piece of data. Also, during a read operation, the MCU 102 may generate an ECC engine tag for codewords retrieved from a non-volatile storage to indicate which type of ECC decoder may be used to decode the codewords.

In one or more embodiments, the ECC engine tag may be generated according to one or many factors. One type of factors may be related to property of the data to be stored by the non-volatile storage controller 100. The property of data may include, but not limited to, usage frequency of a piece of data (e.g., whether it is “hot” or “cold” data), importance of data (e.g., system data vs. user data) and other suitable factors. Another type of factors may be related to characteristics of the storage media to be used, for example, whether the non-volatile storage device to store the data is High-performance NVM (such as MRAM/3DXP/etc.), high quality NAND, or low quality NAND. Based on factor(s) selected for consideration, an ECC engine tag may be generated for an encoding operation with a set of encoding characteristics and for a decoding operation with a set of decoding characteristics. In some embodiments, the criteria to select what factor(s) to be considered and to cover what encoding and decoding characteristics may be configurable, for example, by software or firmware. Moreover, in some embodiments, some characteristics may be required (e.g., ECC code length) and some characteristics may be flexible but with a preference (e.g., encoding/decoding speed). In one embodiment, for example, for frequently used data, high throughput low latency may be preferred; for important data, stronger ECC protection (e.g., stronger error correction capability) may be needed; for high quality NAND, balanced performance and correction ability may be preferred.

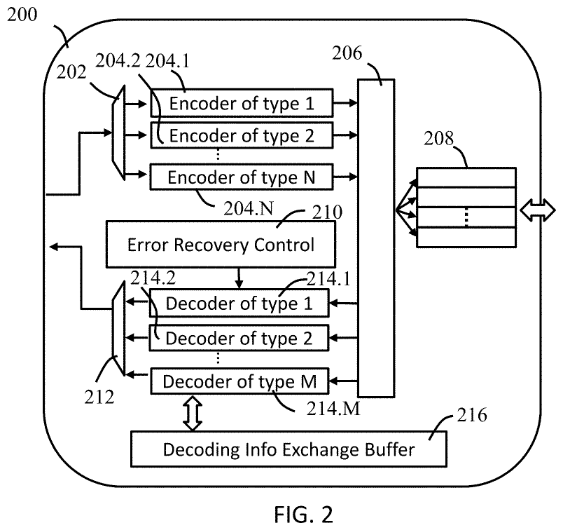

FIG. 2 schematically shows an ECC processor 200 in accordance with an embodiment of the present disclosure. The ECC processor 200 may be an embodiment of the ECC processor 104. The ECC processor 200 may comprise a demultiplexer 202, a plurality of types of encoders 204.1 through 204.N, a memory cross-bar 206, an ECC codeword buffer 208, a multiplexer 212, an optional error recovery control unit 210, a plurality of types of decoders 214.1 through 214.M and an optional decoding information exchange buffer 216.

Each type of encoders 204.1 through 204.N may represent one or more ECC encoders configured with one distinctive set of encoding characteristics, where the integer N may be a positive integer equal to or larger than two. For example, in one embodiment, there may be one encoder of the encoder type 1 204.1, which may be configured for ultra-low latency and high throughput; two encoders of the encoder type 2 204.2, which may be configured for balanced latency and throughput; and four encoders of the encoder type N 204.N, which may be configured for ultra-high correction capability and ultra-high throughput; and other types of encoders may be configured for other purposes and there may be one or more encoders for each type. In some embodiments multiple encoders of a same type may be implemented by multiple instances of ECC engines, but in some other embodiments multiple encoders of a same type may be implemented by a multi-core ECC engine. For example, two encoders of the encoder type 2 204.2 may be implemented by a two-core ECC engine.

Similarly, each type of decoders 214.1 through 214.M may represent one or more ECC decoders configured with one distinctive set of decoding characteristics, where the integer M may be a positive integer equal to or larger than two. For example, in one embodiment, there may be one decoder of the decoder type 1 214.1, which may be configured for ultra-low latency and high throughput; two decoders of the decoder type 2 214.2, which may be configured for balanced latency and throughput; and four decoders of the decoder type M 214.M, which may be configured for ultra-high correction capability and ultra-high throughput; and other types of decoders may be configured for other purposes and there may be one or more decoders for each type. In some embodiments multiple decoders of a same type may be implemented by multiple instances of ECC engines, but in some other embodiments multiple decoders of a same type may be implemented by a multi-core ECC engine. For example, four decoders of the decoder type M 214.M may be implemented by a four-core ECC engine.

Each set of encoding and decoding characteristics may include, but not limited to, ECC code, error correction capability, latency, and various combinations thereof. One set of characteristics may be distinctive from any other set of characteristics if at least one of its characteristics is not present or different in any other set. In one embodiment, the numbers N and M may be equal and each type of encoder may be matched with a corresponding type of decoder. For example, the encoder type 1 204.1 and decoder type 1 214.1 may be configured for ultra-low latency and high throughput; the encoder type 2 204.2 and decoder type 2 214.2 may be configured for balanced latency and throughput; and the encoder type N 204.N and decoder type N 214.N may be configured for ultra-high correction capability and ultra-high throughput; and other types of encoders and decoders configured for other correspondingly matching characteristics. In another embodiment, the numbers of N and M may be equal but the types of encoders do not match the types of decoders one by one. For example, some encoders do not have correspondingly matched decoders or vice versa. In yet another embodiment, the numbers of N and M may be different and the types of encoders do not match the types of decoders one by one.

Some encoding and decoding characteristics may be performance requirements, which may include, but not limited to: ultra-low latency and high throughput, balanced latency and throughput, ultra-high correction capability and ultra-high throughput, and/or any combination(s) of latency, error correction capability, throughput and other characteristics. Some other encoder and decoding characteristics may affect performance, such as, but not limited to, ECC code. For example, longer ECC code may take longer time to encode and decode but may provide stronger error recovery protection. It should be noted that any type of decoder may decode codewords generated by more than one type of encoders regardless of the performance requirements as long as the ECC “code” may be the same (e.g., same parity check matrix, or same coder generation polynomial). Therefore, in one embodiment, there may be one subset of plurality of types of encoders and one subset of plurality of types of decoders configured for one ECC code, and another subset of plurality of types of encoders and another subset of plurality of types of decoders configured for a different ECC code.

The ECC codeword buffer 208 may be a storage unit for storing ECC encoded codewords before the codewords being transmitted via the second interface 112 to non-volatile storage devices during a program operation (e.g., write operation) and after the codewords being received from the second interface 112 during a read operation. In some embodiments, the ECC codeword buffer 208 may be implemented by a memory bank. In one embodiment, the ECC codeword buffer 208 may be shared by both write (“PROG”) and READ paths due to the fact that one physical channel can be occupied by either PROG or READ data traffic, but not both. In another embodiment, the ECC codeword buffer 208 may have separate portions for write and read paths respectively. In yet another embodiment, the ECC codeword buffer 208 may be implemented as two separate buffers for write and read paths respectively.

During a program operation, a PROG path in the ECC processor 200 may comprise the demultiplexer 202, the plurality of types of encoders 204.1 through 204.N, the memory cross-bar 206 and the ECC codeword buffer 208. For example, in a program operation, a piece of data may be received at the demultiplexer 202. An ECC engine tag may be generated by the MCU 102 and associated with the piece of data to indicate to the demultiplexer 202 to which type of ECC encoder the piece of data may be routed. That is, in a program operation, the ECC engine tag may be used to route a piece of data received from a host to a selected type of ECC encoder. The selected type of ECC encoder may then encode the data and send the codeword(s) to the ECC codeword buffer 208 via the memory cross-bar 206.

In some embodiments, multiple non-volatile storage devices that may have different characteristics may be coupled to an embodiment of the non-volatile storage controller 100 and the ECC engine tag associated with the piece of data may also be used to indicate to which non-volatile storage device or to which kind of non-volatile storage device the codeword(s) may be sent. That is, in an embodiment that may have a plurality of non-volatile storage devices that may have different characteristics, the ECC engine tag may also indicate which non-volatile storage device or which kind of non-volatile storage device may be used to store the codeword(s) generated from the piece of data.

Moreover, in some embodiments, during a program operation, a first ECC engine tag may be generated to select a first type of encoder to achieve a first set of encoding characteristics. During operation, the MCU 102 may be configured to generate a second ECC engine tag to select a second type of encoder to achieve a second set of encoding characteristics. For example, initially, the encoder type 1 204.1 may be selected to achieve the best performance in terms of latency and high throughput. During operation, it may be determined that ultra-high performance correction capability may be needed so the ECC engine tag for the encoder type N 204.N may be generated and the encoder type N 204.N may be activated to achieve the ultra-high performance correction capability. In some embodiments, the switching between different types of encoders may be determined based on non-volatile storage device characteristics, such as error count, PROGRAM/ERASE (P/E) cycle, programming time, access latency, etc.

During a read operation, a READ path may comprise the ECC codeword buffer 208, the memory cross-bar 206, the plurality of types of decoders 214.1 through 214.M, and the multiplexer 212. The read operation may trigger one or more commands to retrieve codewords stored in a non-volatile storage device. The codewords retrieved from the non-volatile storage device may be temporarily stored in the ECC codeword buffer 208. An ECC engine tag may be generated (e.g., by the MCU 102) for the codewords and the codewords may be routed from the ECC codeword buffer 208 via the memory cross-bar 206 to one type of decoder 214 according to the ECC engine tag.

Similar to the encoding operations, in some embodiments, during a read operation, a first ECC engine tag may be generated to select a first type of decoder to achieve a first set of decoding characteristics. During operation, the MCU 102 may be configured to generate a second ECC engine tag to select a second type of decoder to achieve a second set of decoding characteristics. For example, initially, the decoder type 1 214.1 may be selected to achieve the best performance in terms of latency and high throughput. During operation, it may be determined that ultra-high performance correction capability may be needed so the ECC engine tag for the decoder type N 214.N may be generated and the decoder type N 214.N may be activated to achieve the ultra-high performance correction capability. In some embodiments, the switching between different types of decoders may be determined based on non-volatile storage device characteristics, such as error count, PROGRAM/ERASE (P/E) cycle, programming time, access latency, etc.

In some embodiments, during a program operation, a first ECC engine type 1 204.1 may be one scheme of code encoder (e.g., Bose-Chaudhuri-Hocquenghem (BCH)) to achieve shortest encoding and decoding latency. Codewords generated from the first type of encoder may be written to nonvolatile memory with short access latency, e.g., MRAM, 3DXP, RRAM, SLC NAND, and NRAM. Therefore, during a read operation, ECC codewords stored in such nonvolatile memory with short access latency can be decoded with minimum delay, creating a fast system response. Encoder type 2 204.2 may be another scheme of code encoder (e.g., Low-Density-Parity-Check (LDPC)) encoder to achieve the best error correction capability. Codewords generated from the second type of encoder may be written to nonvolatile memory with longer access latency, e.g., MLC NAND or TLC NAND.

Moreover, in some embodiments, a codeword associated with an ECC engine tag may be first decoded by a first type of decoder indicated by the ECC engine tag and when the decoding fails, a second type of decoder may be used to try to decode the codeword without generating another ECC engine tag for the second type of decoder. For example, initially, the decoder type 1 214.1 may be selected to achieve the best performance in terms of latency and high throughput. But during operation, the decoder type 1 214.1 may fail to decode one or more codewords associated with the ECC engine tag that indicates decoder type 1 214.1 should be used for them. The failed codewords may be routed to another type of decoder that may have a stronger decoding capability (e.g., decoder type N 214.N configured with ultra-high performance correction capability) without an ECC engine tag for the other type of decoder. In these embodiments, the same ECC engine tag may be utilized to associate or retrieve the related ECC code information and non-volatile storage device characteristics that may be passed to the first type of decoder when the first type of decoder is used and then to the second type of decoder when the second type of decoder is triggered. In one embodiment, the switching between different types of decoders may be controlled by configuration of the error recovery control (ERC) 210.

The ERC 210 may be an optional component for setting a recovery control to handle one or more errors in a decoding process. For example, the ERC 210 may be configured to perform error recovery flow control when the current type of decoder fails to decode the current codeword or fails to make progress in decoding the current codeword after many decoding iterations. The ERC 210 may be implemented in a hardware state machine, a microcontroller or microprocessor. In one embodiment, the ERC 210 may have an exemplary configuration such that the ERC 210 may extract the ECC tag from the current type of decoder (e.g., the decoder type 1 214.1) when decoding fails, and passes the corresponding ECC TAG to a second type of decoder with a stronger correction capability (e.g., the decoder type N 214.N). Once the second type of decoder is activated with the associated ECC tag, it may start decoding the original codeword.

Moreover, the ERC 210 may have a second exemplary configuration such that one ECC tag may be associated with two types of decoders to operate coordinately by utilizing the decoding information exchange buffer 216 to share decoding results between different types of decoders. In some embodiments, a first decoder may fail to decode a codeword but still generate some decoding results. For example, during the decoding process, the first decoder may generate and collect information, such as, but not limited to, which bit may have been flipped, how many times a bit may be flipped, log-likelihood ratio (LLR) that may indicate reliability of a bit, etc. Such information may be collectively referred to as the decoding results, and these decoding results may be stored into the decoding information exchange buffer 216 by the first decoder and accessed by a second decoder when the first decoder fails. By sharing decoding information from a preceding decoder with a subsequent decoder, the subsequent decoder may take advantage of the previous results from the previous decoder. Therefore overall ECC correction capability may be improved.

In addition, the ERC 210 may have a third exemplary configuration such that the ERC 210 may be configured to sustain a target ECC throughput by trying decoding any incoming codewords at a first type of decoder that decodes fast and moving failed codewords to a second type of decoder that decodes slower than the first type of decoder but has a stronger correction capability. When those failed codewords are successfully decoded, and the decoded user data may then be sent to a host (e.g., via the interface 110).

In some embodiments, the MCU 102 may be configured to perform error recovery control functions. For example, the MCU 102 may be configured to re-generate a new ECC tag for switching a type of decoder when the current type of decoder fails to decode a codeword. In contrast, when the error recovery control may be implemented by the ERC 210, the ERC 210 may be designed to pre-configure the error recovery strategy so that it knows when and how to combine different types of decoders together using one ECC TAG during the decoding operations. (e.g., no need to re-generate a new ECC TAG when switching decoders).

As used herein, a type of encoder, decoder or ECC engine may refer to one scheme of ECC (such as but not limited to, Bose-Chaudhuri-Hocquenghem (BCH) or Low-Density-Parity-Check (LDPC)), or one level of a particular ECC scheme (such as but not limited to, a certain code or a certain length of code of BCH or LDPC), or one particular implementation of a BCH or LDPC (such as but not limited to, hard decoding, soft decoding or variations of decoding techniques). It should be noted that a codeword encoded with one ECC scheme (e.g., BCH) may not be decoded by a different ECC scheme (e.g., LDPC), and thus, a switch from a first type of decoder to a second type of decoder may mean a switch from a first type of decoder to a second type of decoder that is compatible with the first type of decoder. That is, when switching from a first type of decoder to a second type of decoder, both the first type of decoder and the second type of decoder may be suitable to decode the codeword.

It some embodiments, a decoder failure of a first type of decoder that implements a first ECC scheme may prompt all future data written to the storage media to switch to a second type of encoder that implements a second ECC scheme that is different from the first ECC scheme. For example, a read operation may be performed on a storage media. The storage media may store data encoded with a first type of encoder implemented in a first ECC scheme (e.g., BCH) and an initial read operation may be performed with a first type of decoder implemented in the first ECC scheme (e.g., BCH) that corresponds to the first type of encoder. The first type of decoder, however, may have difficulty in decoding the encoded data. To successfully decode the encoded data that's already stored in the storage media, another type of decoder implemented in the first ECC scheme (e.g., BCH) but with a stronger decoding capability may be used. For future data to be written to the storage media, a second type of encoder implemented in a second ECC scheme (e.g., LDPC) may be used. In an embodiment, the LDPC code may be stronger than the BCH code and after a failure of BCH code, the data written to the storage media may be switched from a being encoded by BCH code to being encoded by LDPC code. And all future read of the data encoded with the second type of encoder may be decoded first by a second type of decoder implemented in the second ECC scheme, and if that fails, may be switched to another type of decoder implemented in the second ECC scheme. In an embodiment, the ERC 210 may be configured to perform the switching between different ECC schemes.

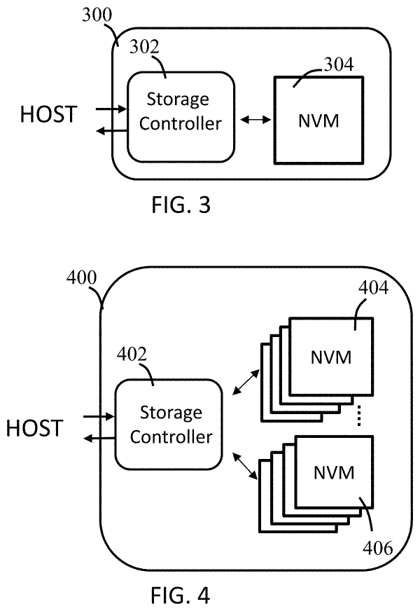

FIG. 3 schematically shows a non-volatile storage system 300 in accordance with an embodiment of the present disclosure. The non-volatile storage system 300 may comprise a non-volatile storage controller 302 and a non-volatile memory (NVM) 304. The non-volatile storage system 300 may provide data storage and/or access to stored data to a host when it is coupled to the host. The non-volatile storage controller 302 may be an embodiment of the non-volatile storage controller 100. The NVM 304 may be represent one or more non-volatile storage devices of a same type (e.g., a high-performance media or a regular-performance media) and these one or more non-volatile storage devices may be configured to work in multiple error correction and latency conditions. The non-volatile storage controller 302 may comprise a plurality of types of ECC encoders and a plurality of types of ECC decoders that support multiple error correction and latency requirements.

In one embodiment, for example, the NVM 304 may be a high-performance NVM, and the non-volatile storage controller 302 may comprise a plurality of types of encoders and a plurality of types of decoders including a first type of encoder and a first type of decoder configured for the best performance in terms of latency and high throughput (e.g., an encoder of type 1 204.1 and a decoder of type 1 214.1), and a second type of encoder and a second type of decoder configured for ultra-high error correction performance (e.g., ECC engine 106.N that may include a pair of encoder 204.N and decoder 214.N). The non-volatile storage system 300 may use the first type of encoder or decoder when best performance in terms of latency and high throughput for encoding or decoding may be needed and the second type of encoder or decoder when ultra-high error correction capability for encoding or decoding may be needed. Therefore, embodiments with a single type of storage media (e.g., a high-performance media such as MRAM, 3DXP) may be configured to achieve the best performance in terms of latency and high throughput, for the target storage media. Within the same type of ECC engines, multi-level ECC engines are activated/switched when system requirement is changed or error recovery is needed.

FIG. 4 schematically shows a non-volatile storage system 400 in accordance with another embodiment of the present disclosure. The non-volatile storage system 400 may comprise a non-volatile storage controller 402 and a plurality of non-volatile memories (NVMs) including a first NVM 404 and a second NVM 406. The non-volatile storage system 400 may provide data storage and/or access to stored data to a host when it is coupled to the host. The non-volatile storage controller 402 may be an embodiment of the non-volatile storage controller 100 and comprise a plurality of types of ECC encoders and a plurality of types of ECC decoders that support multiple error correction and latency requirements. The first NVM 404 may be one or more non-volatile storage devices of a first kind and the second NVM 406 may be one or more non-volatile storage devices of a second kind. The NVM 404 and NVM 406 may have different characteristics (e.g., performance and/or quality). In one embodiment, for example, the NVM 404 may be one or more regular NAND devices (e.g., high-quality NAND devices) and the NVM 406 may be one or more low-quality NAND devices (e.g., low-quality NAND devices). In another embodiment, the NVM 404 and NVM 406 may be the same kind of storage media but with different qualities, for example, mixed SLC, TLC and QLC NANDs.

The non-volatile storage controller 402 may comprise a plurality of types of encoders and a plurality of types of decoders, including a first type of encoder and a first type of decoder (e.g., encoder 204.2 and decoder 214.2) configured for the balanced performance and correction ability, and a second type of encoder and a second type of decoder (e.g., encoder 204.N and decoder 214.N) configured for achieving ultra-high performance in terms of correction capability and throughput. During operation, the non-volatile storage system 400 may use the first type of encoder and first type of decoder for the NVM 404 when balanced performance and correction ability may be needed and switch to the second type of encoder and second type of decoder to achieve ultra-high performance in terms of correction capability and throughput. For the NVM 406, the non-volatile storage system 400 may use the second type of encoder and second type of decoder. In some embodiments, all NVMs may be switched to an encoder and decoder that may be configured for ultra-high performance in terms of correction capability and throughput when needed. The switching between different types of encoders and/or decoders may be determined based on NAND characteristics, such as error count, PROGRAM/ERASE (P/E) cycle, programming time, access latency, etc.

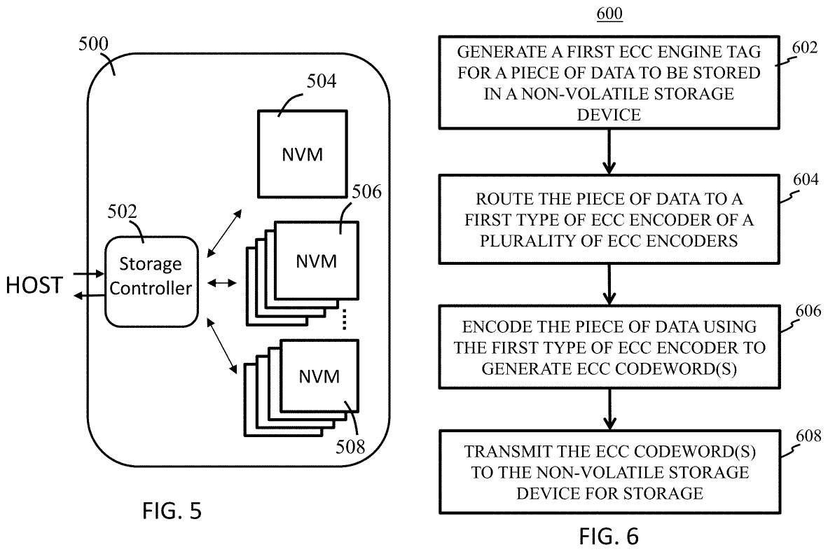

FIG. 5 schematically shows a non-volatile storage system 500 in accordance with yet another embodiment of the present disclosure. The non-volatile storage system 500 may comprise a non-volatile storage controller 502 and a plurality of non-volatile memories (NVMs) including a first NVM 504, a second NVM 506, and a third NVM 508. The non-volatile storage system 500 may provide data storage and access to stored data to a host when it is coupled to the host. The non-volatile storage controller 502 may be an embodiment of the non-volatile storage controller 100 and comprise a plurality of types of encoders and a plurality of types of decoders that support multiple error correction and latency requirements. The NVMs 504, 506 and 508 may be different kinds of storage media or same kinds of storage media but have different characteristics (e.g., performance and/or quality).

In one embodiment, for example, the NVM 504 may be one or more high-performance NVMs (such as MRAM, 3DXP and etc.), the NVM 506 may be one or more regular NAND devices (e.g., a high-quality NAND) and the NVM 508 may be one or more low-quality NAND devices. The non-volatile storage controller 502 may comprise a plurality of types of encoders and decoders including a first type of encoder and a first type of decoder configured for the best performance in terms of latency and high throughput (e.g., encoder 204.1 and decoder 214.1), a second type of encoder and a second type of decoder (e.g., encoder 204.2 and decoder 214.2) configured for the balanced performance and correction ability, and a third type of encoder and a third type of decoder (e.g., encoder 204.N and decoder 214.N) configured for achieving ultra-high performance in terms of correction capability and throughput. During operation, the first type of encoder and the first type decoder may be used for the NVM 504, the second type of encoder and the second type of decoder may be used for the NVM 506 and the third type of encoder and the third type of decoder may be used for the NVM 508.

In some embodiments of the non-volatile storage systems 300, 400 and 500, all NVMs may be switched to one particular type of encoder and decoder (e.g., encoder 204.N and decoder 214.N for ultra-high performance in terms of correction capability and throughput) when needed. The switching between different types of ECC engines may be determined based on the NVM characteristics, such as error count, PROGRAM/ERASE (P/E) cycle, programming time, access latency, etc. Moreover, it should be noted that in some embodiments, different NVMs that have different performance and/or quality may be of the same type. For example, the NVM 406 may be the same type as NVM 404, and NVM 508 may be the same type as NVM 506, but NVMs 406 and 508 may have been used for some time (e.g., “old”) and their performance and quality may have degraded because of use (e.g., compared to the NVMs 404 and 506). Furthermore, at least some embodiments of the non-volatile storage systems 300, 400 and 500 may be multi-channel Solid State Drive (SSD). In these embodiments, the ECC encoders and decoders are not tied to any specific physical channel and may be assigned (and re-assigned) on-the-fly during operation.

Some embodiments of the non-volatile storage systems 300, 400 and 500 may be implemented with Redundant Array of Independent Disks (RAID) configurations. For example, different non-volatile storage devices in an embodiment may be used for data, backup, parity, and/or other RAID features. In one embodiment, for example, a non-volatile storage system may comprise two kinds of non-volatile storage devices and an ECC processor with two types of encoders and two types of decoders. A first type of encoder/decoder and a first kind of non-volatile storage device may be used for data, and a second type of encoder/decoder and a second kind of non-volatile storage device may be used for backup.

FIG. 6 is a flowchart of a process 600 for programming a non-volatile storage device in accordance with an embodiment of the present disclosure. In block 602, a first error correction code (ECC) engine tag may be generated for a piece of data to be stored in a non-volatile storage device. For example, the piece of data may be received by a non-volatile storage system that includes a plurality of kinds of non-volatile storage device. One of the non-volatile storage devices may be selected to store the data based on one or more factors (e.g., importance of data, usage frequency, etc.) The ECC engine tag may be generated according to the characteristics of the selected non-volatile storage device. In block 604, the piece of data may be routed to a first type of ECC encoder of a plurality of types of ECC encoders according to the first ECC engine tag. For example, the first type of ECC encoder may be configured with a set of encoding characteristics that satisfy the requirement for storing the data. In block 606, the piece of data may be encoded using the first type of ECC encoder to generate ECC codeword(s). In block 608, the ECC codeword(s) may be transmitted to the non-volatile storage device for storage. In one or more embodiments, the non-volatile storage system may be a multi-channel NVM system.

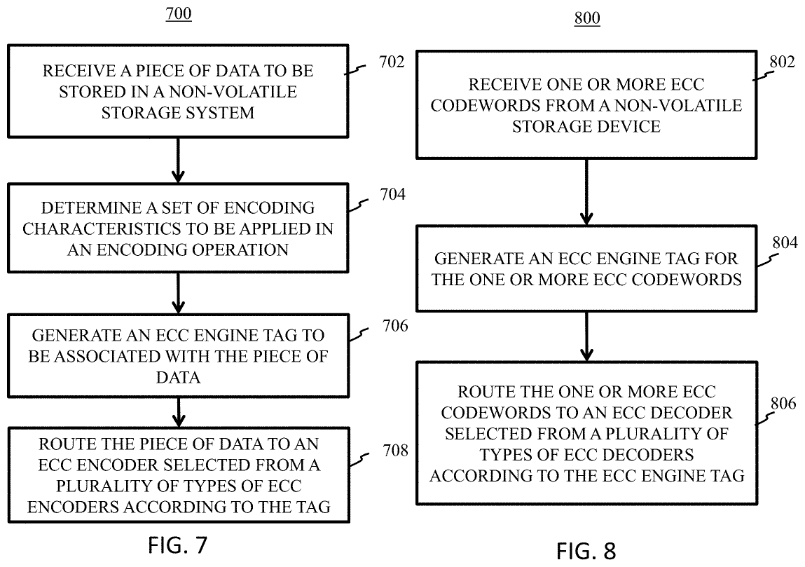

FIG. 7 is a flowchart of another process 700 for storing data in a non-volatile storage system in accordance with an embodiment of the present disclosure. In block 702, a piece of data to be stored in a non-volatile storage system may be received. For example, in an embodiment, the non-volatile storage system may be coupled to a host and the piece of data to be stored in the non-volatile storage system may be received from the host. In block 704, a set of encoding characteristics to be applied in an encoding operation may be determined. In at least one embodiment, the non-volatile storage system may comprise a microcontroller that may be configured to determine what encoding characteristics may be need for the piece of data. For example, one or more factors such as, but not limited to, frequency of usage, importance of data, what kinds of non-volatile storage devices in the non-volatile storage system can be used to store the data, may be taken into consideration. In block 706, an error correction code (ECC) engine tag to be associated with the piece of data may be generated. In block 708, the piece of data may be routed to an ECC encoder selected from a plurality of types of ECC encoders according to the ECC engine tag for the piece of data to be encoded into one or more ECC codewords and stored in a non-volatile storage device of the non-volatile storage system. In various embodiments, the ECC engine tag may be used to indicate which type of encoder may be used to encode the received data for storage and route the codewords to the non-volatile storage device for storing.

FIG. 8 is a flowchart of a process 800 for reading data stored in a non-volatile storage system in accordance with an embodiment of the present disclosure. In block 802, one or more ECC codewords may be received from a non-volatile storage device. The non-volatile storage device may comprise one or more non-volatile storage devices that each has different characteristics. In block 804, an ECC engine tag may be generated for the one or more ECC codewords. In one embodiment, for example, the ECC engine tag may be generated based on ECC code, error correction capability, latency, and various combinations thereof. In block 806, the one or more ECC codewords may be routed to an ECC decoder selected from a plurality of types of ECC decoders according to the ECC engine tag. In at least some embodiments, the plurality of types of ECC decoders may be configured with different set of characteristics and the ECC engine tag may be generated such that the selected ECC decoder may satisfy the requirements for decoding the one or more ECC codewords.

The processes 600, 700 and 800 may be implemented using software (e.g., executable by a computer processor (CPU, GPU, or both)), hardware (e.g., a field-programmable gate array (FPGA) or an application-specific IC (ASIC), firmware, or any suitable combination of the three. For example, in one embodiment, the processes 700 and 800 be programmed in computer processor executable instructions and performed by a computer processor (e.g., a microprocessor or a microcontroller) executing the executable instructions.

Embodiments of the present disclosure may provide a flexible or adaptive ECC system that support high performance non-volatile memory (NVM), high capacity NVM, low performance or low-quality NVM, any future emerging NVM, or any combination thereof. Moreover, embodiments of the present disclosure may provide easy optimization for low latency, high ECC correction capability, or both. For example, an embodiment may be a multi-channel SSD system to support any combination of non-volatile memories while satisfy adequate latency and correction requirement. In addition, embodiments may be applied to balance life cycle of non-volatile memories and performance. For example, an “old” NVM may be used side-by-side with a “new” NVM in an exemplary non-volatile storage system and different quality and characteristics of the “old” and “new” NVM may be accommodated by using different types of encoders and decoders for them.

Embodiments according to the present disclosure may be applied to reduce the overall ECC processing latency, especially in a hybrid SSD system where one or more channels may be equipped with fast non-volatile memories. For example, fast NVMs may need fast ECC to provide the best performance, and thus fast ECC encoder/decoder may be used with faster NVMs and slower ECC encoder/decoder may be used with slower NVMs. Moreover, embodiments according to the present disclosure may be applied to reduce the cost of re-developing a new SSD system when a new non-volatile memory emerges. For example, an exemplary storage controller may support different set of encoding and decoding characteristics and may be used with a new non-volatile memory without any hardware change (e.g., simply updating the firmware will support the new NVM). Upgrading to fast or new NVMs in an embodiment may be easily achieved to further improve the overall system performance.

In an exemplary embodiment, there is provided a method for storing data. The method may comprise generating a first error correction code (ECC) engine tag for a piece of data to be stored in a non-volatile storage device, routing the piece of data to a first type of ECC encoder of a plurality of types of ECC encoders according to the first ECC engine tag, encoding the piece of data using the first type of ECC encoder to generate ECC codeword(s) and transmitting the ECC codeword(s) to the non-volatile storage device for storage.

In one embodiment, the method may further comprise retrieving the ECC codeword(s) from the non-volatile storage, generating a second ECC engine tag for the ECC codeword(s) and routing the ECC codeword(s) to a first type of ECC decoder of a plurality of types of ECC decoders according to the second ECC engine tag.

In one embodiment, the method may further comprise determining that the first type of ECC decoder fails to successfully decode one or more ECC codeword(s) of the ECC codeword(s) and switching to a second type of ECC decoder of the plurality of types of ECC decoders for decoding.

In one embodiment, the method may further comprise determining that the first type of ECC decoder fails to successfully decode one or more ECC codeword(s) of the ECC codeword(s), and switching to a second type of ECC encoder for encoding data to be written to the non-volatile storage, wherein the first type of ECC encoder implements a first ECC scheme and the second type of ECC encoder implements a second ECC scheme that is different from the first ECC scheme.

In one embodiment, the first ECC engine tag may be generated based on property of the piece of data, characteristics of the non-volatile storage device, or both.

In one embodiment, the first type of ECC encoder may be configured with a set of encoding characteristics selected from a plurality of sets of encoding characteristics including: ultra-low latency and high throughput, balanced latency and throughput, and ultra-high correction capability and ultra-high throughput.

In one embodiment, the method may further comprise receiving a second piece of data to be stored, determining that the second piece of data is to be stored in a second non-volatile storage device, generating a second ECC engine tag and routing the second piece of data to a second type of ECC encoder of the plurality of ECC encoders.

In one embodiment, the first type of ECC encoder is a Bose-Chaudhuri-Hocquenghem (BCH) encoder and the second type of ECC encoder is a Low-Density-Parity-Check (LDPC) encoder.

In one embodiment, the non-volatile storage device and the second non-volatile storage device may be two different ones of: a NAND flash memory, a NOR flash memory, a magnetoresistive random Access Memory (MRAM), a resistive random access memory (RRAM), a phase change random access memory (PCRAM), and a Nano-RAM.

In one embodiment, the non-volatile storage device and the second non-volatile storage device may be same kind of non-volatile storage devices with different qualities.

In another exemplary embodiment, there is provided a storage system, which may comprise a storage controller and a microcontroller. The storage controller may comprise an error correction code (ECC) processor that includes a plurality of types of ECC encoders and a plurality of types of ECC decoders. Each type of ECC encoder of the plurality of types of ECC encoders may be configured to perform encoding according to a distinctive set of encoding characteristics, and each type of ECC decoder of the plurality of types of ECC decoders may be configured to perform decoding according to a distinctive set of decoding characteristics. The microcontroller may be configured to generate an ECC engine tag indicating which of the plurality of types of ECC encoders or the plurality of types of ECC decoders to use during operation.

In one embodiment, the storage controller may further comprise: a demultiplexer configured to route data to be stored to a selected type of ECC encoder indicated by the ECC engine tag during a program operation, a multiplexer configured to route ECC codeword(s) from a non-volatile storage device to a selected type of ECC decoder indicated by the ECC engine tag during a read operation, a memory bank configured to buffer ECC codeword(s) generated by the plurality of types of ECC encoders and the ECC codeword(s) from the non-volatile storage device, and a memory cross-bar between the plurality of types of ECC encoders and the memory bank, and between the plurality of types of ECC decoders and the memory bank.

In one embodiment, at least one type of ECC encoder and one type of ECC decoder are implemented in a first ECC scheme, and at least another type of ECC encoder and another type of ECC decoder are implemented in a second ECC scheme that is different from the first ECC scheme.

In one embodiment, the first ECC scheme is Bose-Chaudhuri-Hocquenghem (BCH) and the second ECC scheme is Low-Density-Parity-Check (LDPC).

In one embodiment, the microcontroller may be configured to: generate a first ECC engine tag indicating a first type of ECC decoder to be selected for ECC codeword(s) from a non-volatile storage for decoding, and generate a second ECC engine tag indicating a second type of ECC decoder to be selected for the ECC codeword(s) from the non-volatile storage when the first type of ECC decoder does not satisfy a requirement for decoding.

In one embodiment, the storage controller may further comprise one kind of non-volatile storage device coupled to the storage controller.

In one embodiment, the storage system may further comprise a plurality of non-volatile storage devices including at least two non-volatile storage devices that have different performance and/or storage characteristics.

In one embodiment, the storage system may further comprise a plurality of non-volatile storage devices that include at least a first kind of non-volatile storage device and a second kind of non-volatile storage device. The microcontroller may be configured to: generate a first ECC engine tag to select a first type of ECC encoder and a first type of ECC decoder to achieve a best performance in terms of latency and high throughput for the first kind of non-volatile storage device, and generate a second ECC engine tag to select a second type of ECC encoder and a second type of ECC decoder to achieve a balanced performance and correction ability for the second kind of non-volatile storage device.

In one embodiment, the microcontroller may be further configured to generate the first ECC engine tag for the first kind of non-volatile storage device and the second ECC engine tag for the second kind of non-volatile storage device based on non-volatile storage device characteristics, including one or more of: error count, PROGRAM/ERASE (P/E) cycles, programming time, and access latency.

In yet another exemplary embodiment, there is provided a non-transitory machine-readable medium having information, wherein the information, when read by a hardware processor system, causes the hardware processor system to perform: receiving a piece of data to be stored in a non-volatile storage system, determining a set of encoding characteristics to be applied in an encoding operation, generating an error correction code (ECC) engine tag to be associated with the piece of data, and routing the piece of data to a first ECC encoder selected from a plurality of types of ECC encoders according to the ECC engine tag for the piece of data to be encoded into one or more ECC codewords and stored in a non-volatile storage device of the non-volatile storage system.

In one embodiment, the information, when read by the hardware processor system, further causes the hardware processor system to perform: receiving the one or more ECC codewords from the non-volatile storage device, generating the ECC engine tag for the one or more ECC codewords and routing the one or more ECC codewords to a first ECC decoder selected from a plurality of types of ECC decoders according to the ECC engine tag.

In one embodiment, the information, when read by the hardware processor system, further causes the hardware processor system to perform: determining that the first ECC decoder fails to successfully decode at least one of the one or more ECC codeword(s), and switching to a second ECC encoder for encoding data to be written to the non-volatile storage, wherein the first ECC encoder implements a first ECC scheme and the second ECC encoder implements a second ECC scheme that is different from the first ECC scheme.

In one embodiment, the ECC engine tag may be generated according to encoding characteristics selected from a plurality of sets of encoding characteristics including: ultra-low latency and high throughput, balanced latency and throughput, and ultra-high correction capability and ultra-high throughput.

In one embodiment, at least one type of ECC encoder and one type of ECC decoder may be implemented in Bose-Chaudhuri-Hocquenghem (BCH), and at least another type of ECC encoder and another type of ECC decoder may be implemented in Low-Density-Parity-Check (LDPC).

Any of the disclosed methods and operations may be implemented as computer-executable instructions (e.g., software code for the operations described herein) stored on one or more computer-readable storage media (e.g., non-transitory computer-readable media, such as one or more optical media discs, volatile memory components (such as DRAM or SRAM), or nonvolatile memory components (such as hard drives)) and executed on a device controller (e.g., firmware executed by ASIC). Any of the computer-executable instructions for implementing the disclosed techniques as well as any data created and used during implementation of the disclosed embodiments can be stored on one or more computer-readable media (e.g., non-transitory computer-readable media).

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

What is claimed is:

1. A method for storing data, comprising:
generating a first error correction code (ECC) engine tag for a piece of data to be stored in a non-volatile storage device;
routing the piece of data to a first type of ECC encoder of a plurality of types of ECC encoders according to the first ECC engine tag;
encoding the piece of data using the first type of ECC encoder to generate ECC codeword(s); and
transmitting the ECC codeword(s) to the non-volatile storage device for storage.

2. The method of claim 1, further comprising:
retrieving the ECC codeword(s) from the non-volatile storage;
generating a second ECC engine tag for the ECC codeword(s); and
routing the ECC codeword(s) to a first type of ECC decoder of a plurality of types of ECC decoders according to the second ECC engine tag.

3. The method of claim 2, further comprising:
determining that the first type of ECC decoder fails to successfully decode one or more ECC codeword(s) of the ECC codeword(s); and
switching to a second type of ECC decoder of the plurality of types of ECC decoders for decoding.

4. The method of claim 1, further comprising:
determining that the first type of ECC decoder fails to successfully decode one or more ECC codeword(s) of the ECC codeword(s); and
switching to a second type of ECC encoder for encoding data to be written to the non-volatile storage, wherein the first type of ECC encoder implements a first ECC scheme and the second type of ECC encoder implements a second ECC scheme that is different from the first ECC scheme.

5. The method of claim 1, wherein the first ECC engine tag is generated based on property of the piece of data, characteristics of the non-volatile storage device, or both.

6. The method of claim 5, wherein the first type of ECC encoder is configured with a set of encoding characteristics selected from a plurality of sets of encoding characteristics including: ultra-low latency and high throughput, balanced latency and throughput, and ultra-high correction capability and ultra-high throughput.

7. The method of claim 1, further comprising
receiving a second piece of data to be stored;
determining that the second piece of data is to be stored in a second non-volatile storage device;
generating a second ECC engine tag; and
routing the second piece of data to a second type of ECC encoder of the plurality of ECC encoders.

8. The method of claim 7, wherein the first type of ECC encoder is a Bose-Chaudhuri-Hocquenghem (BCH) encoder and the second type of ECC encoder is a Low-Density-Parity-Check (LDPC) encoder.

9. The method of claim 7, wherein the non-volatile storage device and the second non-volatile storage device are two different ones of: a NAND flash memory, a NOR flash memory, a magnetoresistive random Access Memory (MRAM), a resistive random access memory (RRAM), a phase change random access memory (PCRAM), and a Nano-RAM.

10. The method of claim 7, wherein the non-volatile storage device and the second non-volatile storage device are same kind of non-volatile storage devices with different qualities.

11. A storage system, comprising:
a storage controller, comprising:
an error correction code (ECC) processor including a plurality of types of ECC encoders and a plurality of types of ECC decoders, each type of ECC encoder of the plurality of types of ECC encoders being configured to perform encoding according to a distinctive set of encoding characteristics, and each type of ECC decoder of the plurality of types of ECC decoders being configured to perform decoding according to a distinctive set of decoding characteristics; and
a microcontroller configured to generate an ECC engine tag indicating which of the plurality of types of ECC encoders or the plurality of types of ECC decoders to use during operation.

12. The storage system of claim 11, wherein the storage controller further comprises:
a demultiplexer configured to route data to be stored to a selected type of ECC encoder indicated by the ECC engine tag during a program operation;
a multiplexer configured to route ECC codeword(s) from a non-volatile storage device to a selected type of ECC decoder indicated by the ECC engine tag during a read operation;
a memory bank configured to buffer ECC codeword(s) generated by the plurality of types of ECC encoders and the ECC codeword(s) from the non-volatile storage device; and
a memory cross-bar between the plurality of types of ECC encoders and the memory bank, and between the plurality of types of ECC decoders and the memory bank.

13. The storage system of claim 11, wherein at least one type of ECC encoder and one type of ECC decoder are implemented in a first ECC scheme, and at least another type of ECC encoder and another type of ECC decoder are implemented in a second ECC scheme that is different from the first ECC scheme.

14. The storage system of claim 13, wherein the first ECC scheme is Bose-Chaudhuri-Hocquenghem (BCH), and the second scheme is Low-Density-Parity-Check (LDPC).

15. The storage system of claim 11, wherein the microcontroller is configured to:
generate a first ECC engine tag indicating a first type of ECC decoder to be selected for ECC codeword(s) from a non-volatile storage for decoding; and
generate a second ECC engine tag indicating a second type of ECC decoder to be selected for the ECC codeword(s) from the non-volatile storage when the first type of ECC decoder does not satisfy a requirement for decoding.

16. The storage system of claim 11, further comprising a plurality of non-volatile storage devices including at least two non-volatile storage devices that have different performance and/or storage characteristics.

17. The storage system of claim 11, further comprising a plurality of non-volatile storage devices that include at least a first kind of non-volatile storage device, and a second kind of non-volatile storage device,
wherein the microcontroller is configured to:
generate a first ECC engine tag to select a first type of ECC encoder and a first type of ECC decoder to achieve a best performance in terms of latency and high throughput for the first kind of non-volatile storage device; and
generate a second ECC engine tag to select a second type of ECC encoder and a second type of ECC decoder to achieve a balanced performance and correction ability for the second kind of non-volatile storage device.

18. The storage system of claim 17, wherein the microcontroller is further configured to generate the first ECC engine tag for the first kind of non-volatile storage device and the second ECC engine tag for the second kind of non-volatile storage device based on non-volatile storage device characteristics, including one or more of: error count, PROGRAM/ERASE (P/E) cycles, programming time, and access latency.

19. A non-transitory machine-readable medium having information, wherein the information, when read by a hardware processor system, causes the hardware processor system to perform:
receiving a piece of data to be stored in a non-volatile storage system;
determining a set of encoding characteristics to be applied in an encoding operation;
generating an error correction code (ECC) engine tag to be associated with the piece of data; and
routing the piece of data to a first ECC encoder selected from a plurality of types of ECC encoders according to the ECC engine tag for the piece of data to be encoded into one or more ECC codewords and stored in a non-volatile storage device of the non-volatile storage system.

20. The non-transitory machine-readable medium of claim 19, wherein the information, when read by the hardware processor system, further causes the hardware processor system to perform:
receiving the one or more ECC codewords from the non-volatile storage device;
generating the ECC engine tag for the one or more ECC codewords; and
routing the one or more ECC codewords to a first ECC decoder selected from a plurality of types of ECC decoders according to the ECC engine tag.

21. The non-transitory machine-readable medium of claim 20, wherein the information, when read by the hardware processor system, further causes the hardware processor system to perform:
determining that the first ECC decoder fails to successfully decode at least one of the one or more ECC codeword(s); and
switching to a second ECC encoder for encoding data to be written to the non-volatile storage, wherein the first ECC encoder implements a first ECC scheme and the second ECC encoder implements a second ECC scheme that is different from the first ECC scheme.

22. The non-transitory machine-readable medium of claim 20, wherein the ECC engine tag is generated according to encoding characteristics selected from a plurality of sets of encoding characteristics including: ultra-low latency and high throughput, balanced latency and throughput, and ultra-high correction capability and ultra-high throughput.

23. The non-transitory machine-readable medium of claim 20, wherein at least one type of ECC encoder and one type of ECC decoder are implemented in Bose-Chaudhuri-Hocquenghem (BCH), and at least another type of ECC encoder and another type of ECC decoder are implemented in Low-Density-Parity-Check (LDPC).
